(19) United States
(12) Patent Application Publication
(10) Pub. No.: US 2006/0088660 A1
(43) Pub. Date: Apr. 27, 2006

(54) Methods of depositing lead containing oxides films

(76) Inventors: Matti I. Putkonen, Helsinki (FI); Jenni E. Harjuoja, Helsinki (FI)

Correspondence Address: KNOBBE MARTENS OLSON & BEAR LLP, 2040 MAIN STREET, FOURTEENTH FLOOR, IRVINE, CA, 92614, US

(21) Appl. No.: 10/974,487

(22) Filed: Oct. 26, 2004

(51) Int. Cl. C23C 16/00

(52) U.S. Cl. 427/248.1

(57) ABSTRACT

Lead containing oxide thin films by Atomic Layer Deposition, comprising using a metal-organic lead compound, having organic ligands bonded to a lead atom by carbon-lead bonds, as a source material for the lead oxide. Stoichiometric PbTiO₃ thin films with excellent uniformity can be deposited on substrates by ALD growth using, for example, Ph₄Pb, O₃, Ti(OⁱPr)₄ and H₂O as precursors at 250 and 300° C.

### BACKGROUND OF THE INVENTION

### FIELD OF THE INVENTION

This invention relates generally to the field of microelectronics and in particular to methods of producing lead containing oxide thin films by gas phase deposition methods and, more particularly, by atomic layer deposition (ALD), and to lead containing oxide thin films.

The lead titanate family consists of a large range of solid compounds, such as PZT (lead zirconate titanate), PLT (lead lanthanum titanate) and PLZT (lead lanthanum zirconate titanate). By adding dopants, e.g. lanthanum and zirconium, it is possible to improve the properties of lead titanate (PbTiO₃) for specific thin film applications, e.g. ferroelectric memories, pyroelectric infrared sensors, electro-optic devices and insulator gates in metal-insulator-semiconductor (MIS) diodes.

The perovskite-type PbTiO₃ has a high Curie temperature of 490° C., a relatively low permittivity (compared to other lead titanate family compounds) and a large pyroelectric coefficient. Lead titanate thin films have basically the same physical properties as the bulk material but in memory applications they have low operating voltage and high switching speed.

Thin films of PbTiO₃ have been prepared by different chemical and physical methods. Metal-organic chemical vapor deposition (MOCVD), with all its different variations, such as laser induced-MOCVD, plasma induced-MOCVD and ion beam induced-MOCVD, is the most used deposition method. In addition to conventional CVD methods, the so-called “improved MOCVD” method has been used to deposit a and c-axis-oriented thin films. In such a method, the metal precursor vapors have been alternately introduced into the reactor together with the oxygen source. Other chemical and physical deposition methods used for preparing thin films of PbTiO₃ include rf magnetron sputtering, pulsed laser ablation, the sol-gel method, spin-coating, chemical solution deposition and hybrid chemical methods.

For practical applications, the PbTiO3 films have to meet stringent quality demands. Thus, the films have to be defect-free and they must have low surface roughness. Also the interface between the ferroelectric and the substrate is important. To avoid undesirable interfacial reactions during the semiconductor process, a low deposition temperature is preferred.

Atomic Layer Deposition (ALD—or, as it was earlier called, “Atomic Layer Epitaxy”, abbreviated ALE) is a well-known method for growing high-quality thin films on substrates. The ALD method is based on sequential self-saturating surface reactions, resulting in thin films that have low impurity content and uniform physical properties, including film thickness.

The principles of ALD-type processes have been presented by the inventor of the ALD technology, Dr. T. Suntola, e.g., in Handbook of Crystal Growth 3, Thin Films and Epitaxy, Part B: Growth Mechanisms and Dynamics, Chapter 14, “Atomic Layer Epitaxy”, pp. 601-663, Elsevier Science B.V. 1994, the disclosure of which is incorporated herein by reference.

Extensive selections of ALD precursors and ALD-grown materials have been presented by Prof. M. Ritala and Prof. M. Leskela in a recent review article, Handbook of Thin Film Materials, Vol. 1: Deposition and Processing of Thin Films, Chapter 2 “Atomic Layer Deposition”, pp. 103-159, Academic Press 2002.

However, the known methods of depositing lead containing oxide thin films are not compatible with ALD processes. Further, the lead containing oxide thin films deposited according to known methods do not provide devices with satisfactory performance levels.

With regard to the state of the art and to the various problems encountered, it should also be noted that lead oxide exists in many different forms because lead can adopt a valence state of either +2 or +4. Lead oxides also have many different crystal forms. Consequently, it is difficult to deposit lead oxide thin films containing only one oxide form with a certain crystal form. Earlier studies have shown that lead oxide thin films deposited by metal organic chemical vapor deposition (MOCVD) contain both lead oxide and an oxygen rich form of lead dioxide.

Therefore, there is a need for a repeatable and controlled method of depositing uniform thin films that contain lead oxide.

### SUMMARY OF THE INVENTION

It is an object of the preferred embodiments to eliminate the problems related to the known methods and to provide a novel method of manufacturing lead oxide containing thin films, such as high performance lead titanate (PbTiO₃) for thin film applications.

It is another object of the preferred embodiments to provide a method of producing multicomponent lead oxide films.

These and other objects, together with the advantages thereof over known processes and products, are achieved by the preferred embodiments as hereinafter described and claimed.

Binary lead oxides and ternary, quaternary and more complicated metal oxides containing lead oxide are grown by the ALD process from metal-organic lead precursors that contain organic ligands bonded to the lead atom of the compound by carbon-metal bonds. Surprisingly, it has been found that traditional organo metallic lead precursors in which the metal is bonded to the organic residues via oxygen atoms do not give rise to genuine ALD growth, or ALD growth is achieved only within narrow temperature ranges, and films produced exhibit high levels of impurities. By contrast, the lead precursors utilized in the preferred embodiments result in ALD growth within various temperature ranges and the thin films have low concentrations of residues from the ligands.

The present invention also provides a process for forming lead containing multicomponent oxide thin films by Atomic Layer Deposition on a substrate in a reaction space it also provided in some embodiments.

A process for producing an oxide thin film by Atomic Layer Deposition comprising using as a source material for lead oxide a metal-organic lead precursor, having organic ligands bonded to a lead atom by carbon-lead bonds.

The method for producing multicomponent lead oxide films is mainly characterized by what is stated in the characterizing part of claim 18.

Stoichiometric PbTiO₃ thin films with excellent uniformity can be deposited on substrates by ALD growth using, for example, Ph₄Pb, O₃, Ti(OⁱPr)₄ and H₂O as precursors at substrate temperatures of from about 250° C. to 300° C. At constant deposition temperatures and pulsing ratios, using the disclosed precursors, the film thickness of PbTiO₃ films has been found to be linearly dependent on the number of deposition cycles, indicating genuine ALD growth.

As will appear from the examples below, thin films produced according to the preferred embodiments typically contain only small amounts of hydrogen and carbon impurities according to Time-of-Flight Elastic Recoil Detection Analysis (TOF-ERDA).

Lead titanate films are amorphous after deposition, but crystalline PbTiO₃ thin films can be obtained by annealing the amorphous films at temperatures above 500° C., e.g. 600° C., or more. By converting the amorphous films into crystalline films, higher dielectric constants are obtained.

Next the invention will be discussed more closely with the aid of a detailed description and a working example.

### BRIEF DESCRIPTION OF THE DRAWINGS

FIG. 1 shows a structural (A) and a shaded ball drawing (B) of a tetraphenyl lead (Ph₄Pb) molecule.

FIG. 2 shows an example of a process sequence used for depositing a multimetal oxide thin film.

FIG. 3 shows the growth rate of PbO₂ thin films as a function of deposition temperature.

FIG. 4 shows x-ray diffraction diagrams of PbO₂ films deposited from selected Pb precursors.

FIG. 5 shows the deposition rate of lead oxide thin films at selected temperatures from Ph₄Pb with different material pulse lengths.

FIG. 6 shows the effect of different Ti/Pb precursor pulsing ratios on the titanium and lead content in Pb—Ti—O films deposited at selected temperatures.

FIG. 7 shows the effect of annealing on PbTiO₃ films as revealed by x-ray diffraction.

### DETAILED DESCRIPTION OF THE PREFERRED EMBODIMENT

As known in the art, there are various variations of the basic ALD method, including PEALD (plasma enhanced ALD) in which plasma is used for activating reactants. Conventional ALD or thermal ALD refers to an ALD method where plasma is not used but where the substrate temperature is high enough for overcoming the energy barrier (activation energy) during collisions between the chemisorbed species on the surface and reactant molecules in the gas phase so that up to an atomic (elemental) or a molecular (compound) layer of thin film grows on the substrate surface during each ALD pulsing sequence. For the purpose of the present invention, ALD covers both PEALD and thermal ALD.

### DEFINITIONS

As used herein, “an ALD type process” generally refers to a process for producing thin films over a substrate, in which process a solid thin film is formed molecular layer by molecular layer due to self-limiting and self-saturating chemical reactions on heated surfaces. In the process, gaseous reactants, i.e. precursors, are conducted into a reaction space of an ALD type of a reactor and contacted with a substrate located in the chamber to provide a surface reaction. The pressure and the temperature of the reaction space are adjusted to a range where physisorption (i.e. condensation of gases) and thermal decomposition of the precursors are avoided. Consequently, only up to one monolayer (i.e. an atomic layer or a molecular layer) of material is deposited at a time during each pulsing cycle. The actual growth rate of the thin film, which is typically presented as Å/pulsing cycle, depends, for example, on the number of available reactive surface sites on the heated surface and bulkiness of the chemisorbing molecules. Gas phase reactions between precursors and any undesired reactions of by-products are inhibited because material pulses are separated from each other by time and the reaction space is purged with an inactive gas (e.g. nitrogen or argon) and/or evacuated between material pulses to remove surplus gaseous reactants and reaction by-products from the chamber.

A “reaction space” designates generally a reactor or a reaction chamber in which the conditions can be adjusted so that deposition of a thin film is possible.

In context of the present application, “an ALD type reactor” means a reactor where the reaction space is in fluid communication with an inactive gas source and at least one, preferably at least two precursor sources that can be pulsed, i.e. the precursor vapour pushed from the precursor source can be introduced as a gas pulse into the reaction space. The reaction space is also preferably in fluid communication with a vacuum generator (e.g. a vacuum pump), and the temperature and pressure of the reaction space and the flow rates of gases can be adjusted to a range that makes it possible to grow thin films by ALD type processes.

In context of the present application, “rare earth elements” means elements of the group 3 (scandium Sc, yttrium Y, lanthanum La) and lanthanide series (cerium Ce, praseodymium Pr, neodymium Nd, samarium Sm, europium Eu, gadolinium Gd, terbium Tb, dysprosium Dy, holmium Ho, erbium Er, thulium Tm, ytterbium Yb and lutetium Lu) of the periodic table of elements.

“Source material” and “precursor” are used interchangeably in the present application to designate a volatile or gaseous compound, which can be used as a starting compound for the corresponding metal oxide of the thin film.

Source Materials

Lead Precursors

In the preferred embodiments, metal-organic lead precursors containing organic ligands which are bonded to the lead atom via carbon-lead bonds are used as source materials in the production of thin films in ALD reactors. The metal-organic lead compound has 2 or 4 alkyl ligands or ligands comprising aromatic groups. In particular embodiments, the metal-organic lead compound preferably has the formula
L¹L²L³L⁴Pb
wherein each L¹, L², L³ and L⁴ is independently selected from
linear or branched C1-C20 alkyl or alkenyl groups,
halogenated alkyl or alkenyl groups, wherein at least one hydrogen atom is replaced with fluorine, chlorine, bromine or iodine atom,
carbocyclic groups, such as aryl, preferably phenyl, tolyl and xylyl, alkylaryl groups including benzyl, cyclic dienes, halogenated carbocyclic groups, and
heterocyclic groups (provided that these are bonded to the metal via a carbon atom.

According to a preferred embodiment, the precursors contain four organic ligands selected from the group consisting of optionally substituted, linear, branched or cyclic alkyl groups or aryl groups. “Alkyl” stands, for example, for an alkyl group, selected from methyl, ethyl, n- and i-propyl, and n-, sec- and t-butyl. In each ligand, and in different ligands, the alkyl groups may be the same or different. Above, the chlorinated alkyl and alkenyl groups are mentioned. Other substituents are also possible, such as hydroxyl, carboxy, thio, silyl and amino groups.

Specific examples of the present novel precursors are tetraphenyl lead and tetraethyl lead.

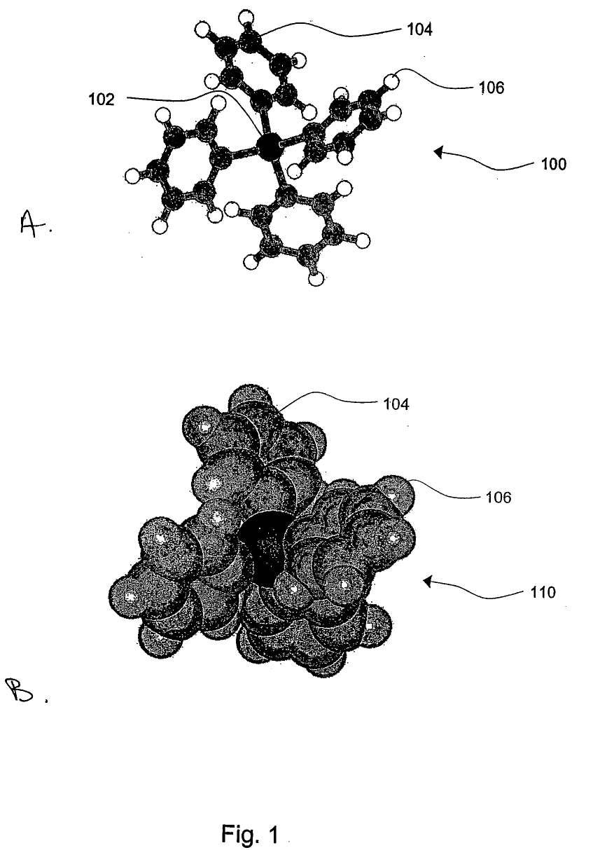

Turning now to the drawings, it can be noted that FIG. 1 depicts a structural 100 and a shaded ball drawing 110 of a tetraphenyl lead Ph4Pb molecule. The molecules consists of lead 102, carbon 104 and hydrogen 106 atoms. The Pb atom 102 in the center of the Ph₄Pb molecule is shielded with phenyl C₆H₅ ligands resulting in good thermal stability of the precursor. It is possible to further improve the shielding effect of the ligands on the center Pb atom and to increase the thermal stability of the Pb precursor by modifying the phenyl ligands so that there are, e.g., alkyl group(s) attached to the carbon ring instead of hydrogen atom(s).

Second Metal Precursors

The second metal source material needed for ternary or higher metal oxides can be a metal compound or a complex metal compound comprising two or more metals. The metals are typically selected from the group of volatile or gaseous compounds of transition metals and main group metals according to the system recommended by IUPAC in the periodic table of elements, i.e., elements of groups comprising
1(Li, Na, K, Rb, Cs);
2(Mg, Ca, Sr, Ba);
3(Sc, Y, La, Ce, Pr, Nd, Pm, Sm, Eu, Gd, Th, Dy, Ho, Er, Tm, Yb, Lu);
4(Ti, Zr, Hf);
5(V, Nb, Ta);
6(Cr, Mo, W);
7(Mn, Re);
8(Fe, Ru, Os);
9(Co, Rh, Ir);
10(Ni, Pd, Pt);
11(Cu, Ag, Au);
12(Zn, Cd, Hg);
13(Al, Ga, In, Ti);
14(Si, Ge, Sn); and/or
15(Sb, Bi).

Since the properties of each metal compound vary, the suitability of each metal compound for the use in the process of the present invention has to be considered. The properties of the compounds can be found, e.g., in N. N. Greenwood and A. Earnshaw, Chemistry of the Elements, 1^{st} edition, Pergamon Press, 1986.

Typically, suitable second metal source materials are preferably selected from the group comprising
halides, preferably fluorides, chlorides, bromides or iodides;
metal organic compounds, preferably alkoxides (cf. the titanium isopropoxide of the Example 1);
alkylamino;
cyclopentadienyl, alkyl derivatives of cyclopentadienyl;
dithiocarbamate;
amidinate;
beta-ketoiminate;
beta-diketiminate; and
beta-diketonate compounds of the desired metal(s).

Double metal precursors, i.e. molecules containing two metals in a discrete stoichiometric ratio, may also be used. Examples of double metal precursors include double metal alkoxides that have been presented, e.g., in a chemical catalogue from Gelest, Inc. (Edited by B. Arkles, Gelest, Inc. 1995, pp. 344-346).

Oxygen Precursors

An oxygen source material is preferably selected from the group comprising
water;
oxygen;
hydrogen peroxide H₂O₂, aqueous solutions of hydrogen peroxide;
ozone O₃;
oxides of nitrogen including NO₂, NO, N₂O;
halide-oxygen compounds;
peracids —C(═O)—O—OH;
alcohols, such as methanol, ethanol, propanol and isopropanol;
alkoxides;
oxygen-containing radicals, such as O* and HO*, wherein * denotes an unpaired electron; and
mixtures thereof.

Ozone gas is often diluted with oxygen gas due to the ozone manufacturing methods. The oxygen source material vapor is optionally diluted with inactive gas.

Process Conditions

The reaction temperature can vary depending on the evaporation temperature and the decomposition temperature of the precursor. A typical range is about 150 to 400° C., in particular about 180 to 380° C. Based on the results obtained for crystallization, it is particularly preferred to grow lead titanate films from tetraphenyl lead at temperatures below about 300° C., typically about 200 to 290° C., e.g. about 250° C., to achieve crystallization of the films at modestly high annealing temperatures.

In some preferred embodiments, gas phase pulses of the evaporated metal-organic lead compound mixed with inactive carrier gas or without the inactive carrier gas are introduced into an ALD reactor, where they are contacted with a suitable substrate. The deposition can be carried out at normal pressure, but it is preferred to operate the method at reduced pressure. The pressure in the reactor is typically 0.01-20 mbar, preferably 0.1-5 mbar.

The substrate temperature is preferably low enough to keep the bonds between thin film atoms intact and to prevent thermal decomposition of the gaseous reactants. On the other hand, the substrate temperature is preferably high enough to keep the source materials in gaseous phase, i.e., condensation of the gaseous reactants is preferably avoided. Further, the temperature is preferably sufficiently high to provide the activation energy for the surface reaction.

At these conditions, the initial amount of reactants bound to the surface will be determined by the available surface area. With subsequent reactant pulses, the surface reactions will be dependent upon the number of available reactive surface sites in addition to the three-dimensional structure of the reactants. Thus, the surface reactions will be self-limiting and self-saturating.

For further details on the operation of a typical ALD process, reference is made to the documents cited above and to Example 1 below.

The substrate can be of various types. Examples include silicon, silica, coated silicon, germanium, silicon-germanium alloys, copper metal, noble and platinum metals group including silver, gold, platinum, palladium, rhodium, iridium and ruthenium, various nitrides, such as transition metal nitrides, e.g. tantalum nitride (TaN), various oxides, such as platinum group metal oxides, e.g. ruthenium dioxide (RuO₂), various carbides, such as transition metal carbides, e.g. tungsten carbide (WC), transition metal nitride carbides, e.g. tungsten nitride carbide (WnₓC_{y}) and dielectric surfaces, such as high-k oxides serving as interfacial layers, e.g. rare earth oxides such as Al₂O₃ or La₂O₃.

Similarly, surfaces comprising lead oxide or a ternary, quaternary or more complicated metal oxide containing lead oxide, can serve as a substrate surface for further deposition of thin films including noble and platinum metals group and other materials presented in the previous paragraph. The resulting multilayer sandwich structure is utilized for example in metal-insulator-metal (MIM) devices.

Conventionally, the preceding thin film layer deposited will form the substrate surface for the next thin film.

In order to convert the adsorbed (chemisorbed) lead precursor into lead oxide, the reactor is evacuated and/or purged with a purge gas comprising an inactive gas. Next a gas phase pulse of an oxygen source material, such as ozone O3, is introduced into the reactor. The oxygen source material vapor is optionally diluted with inactive gas.

By alternating the reactions of the lead precursor and the oxygen source material, a lead containing oxide thin film can be deposited. Typically, a growth rate of about 0.10 to 0.20 Å/cycle is achieved.

In order to produce multicomponent oxide films, a second metal source material can be introduced at ALD conditions.

In particular, a multicomponent oxide film preferably consists essentially of Pb oxide and of an oxide selected from Bi, Ca, Sr, Cu, Ti, Ta, Zr, Hf. V, Nb, Cr, W, Mo, Al, rare earths (e.g. La) and/or Si oxides and, thus, the corresponding gaseous or volatile metal compounds are preferably used in the methods of the present invention. The second (third etc.) metal source material can be oxidized using the same or another oxygen source material as for the lead precursor.

Titanium, lanthanum and zirconium are particularly interesting as sources of a second and/or third and/or fourth metal in ternary and other multicomponent lead containing oxides. Multicomponent Pb/Ti and Pb/Ti and La and/or Zr oxides are potentially valuable as high-k dielectric material.

According to one preferred embodiment, multicomponent films are produced by feeding alternating pulses of the various metal precursors (followed by the above mentioned oxygen source pulses) into an ALD reactor. This embodiment based on “mixing cycles” will give rise to a ferroelectric phase after deposition. Typically, the ratio of cycles consisting of lead containing precursor followed by oxygen source pulses to cycles consisting of a second metal source followed by the corresponding oxygen source pulses is about 50:1 to about 1:50, preferably about 40:1 to about 1:40, and more preferably about 35:1 to about 1:1 (metal to metal, based on moles). Typically, there is a small stoichiometric surplus of some 1 to 20 at-% of titanium in lead titanate films.

In theory, a stoichiometric oxide ABO3, wherein A and B denote two different metals, can be obtained simply by pulsing the two metal precursors and corresponding oxygen sources alternately and the growth rate of the ternary oxide can be predicted by summing the growth rates of the constituent oxides. In practice, however, film growth depends on the different reactivities of the precursors. The effect of surface chemistry usually causes changes in relative growth rate, which can be determined by comparing the observed film thickness with the theoretical thickness calculated from the growth rates of binary oxides. According to the present invention, the relative growth rate of PbTiO₃ was found to be dependent on the pulsing ratio of precursors and also on the deposition temperature. Maximum relative growth rates were obtained at 250 and 300° C. by using Ti:Pb pulsing ratios 1:15 and 1:50, respectively, being 155% at 250° C. and 190% at 300° C.

Another preferred embodiment comprises preparing multicomponent films by depositing laminar layers of each metal oxide and annealing the laminar layers together at increased temperatures to provide a crystalline phase. In this way, first an amorphous structure is provided and a high dielectric material is obtained by annealing at temperatures in excess of 500° C., in particular in excess of 700° C., in the presence of oxygen (such as in the presence of air) or an oxygen-containing compound (e.g. N₂O) or in the presence of an inert gas (e.g. N₂ or Ar).

Thus, the polycrystalline tetragonal perovskite PbTiO₃ phase (JCPDS Card No 6-452) can be observed by XRD when stoichiometric or lead-rich films deposited at 250° C. are annealed either in nitrogen or oxygen atmosphere for at least 1 minute, preferably for 5 to 60 minutes, typically about 10 minutes, at a temperature in the range of 600 to 900° C. Annealing in oxygen is a particularly preferred way of crystallizing PbTiO₃ for lead oxide films deposited at 250° C. Films annealed in oxygen are smooth and shiny even after annealing at 900° C. By contrast, annealing in nitrogen is a preferred embodiment for the films deposited at 300° C.

In the above embodiments, where a second and further metal precursors are fed into an ALD reactor, a gas phase pulse of an oxygen source material is preferably, but not necessarily, fed into the ALD reactor after each metal precursor pulse. A purge gas pulse preferably separates the oxygen precursor pulse from the metal precursor pulse.

The present novel thin film oxide materials will find extensive use in semiconductor industry applications, such as in integrated circuit fabrication. In particular lead titanate thin films can be used in pyroelectric infrared sensors, electro-optic devices, and in insulator layers of metal-insulator-semiconductor (MIS) or metal-insulator-metal (MIM) memory cell structures.

The following non-limiting examples illustrate the invention.

### EXAMPLE 1

### ALD Processing of Lead Oxide Films

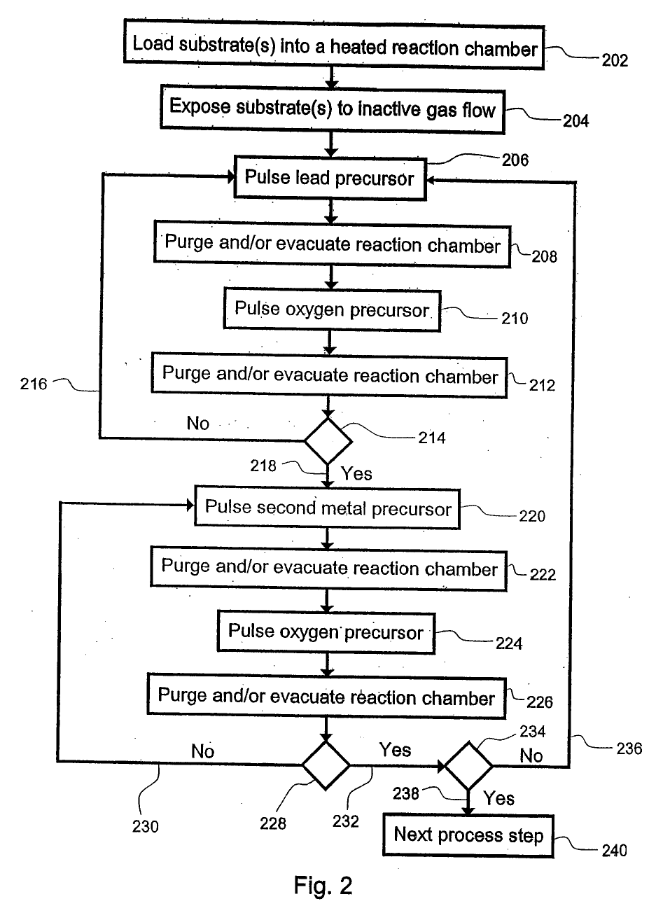

FIG. 2 shows an example of a process sequence that can be used for depositing a multimetal oxide (e.g. PbTiO₃) thin film. Throughout of the history of ALD (ALE), nested pulsing cycles have been utilized in the control program for ALD film growth. The control program stored in a computer memory and executed by a CPU comprises nested pulsing cycle routines with programmable global 234 and local pulsing cycle counters 214, 228. Global pulsing cycle counter 234 takes care of the predetermined total thin film thickness. Each local pulsing cycle counter 214, 228 takes care of the predetermined thickness of the sublayers, e.g. binary metal oxides, that form the thin film.

A thin film may consist of clearly distinguishable sublayers that have different phases, such as chemical composition or crystallinity, when compared to each other. This kind of film is called as a nanolaminate. Deposited sublayers may also be so thin, in the order of a molecular layer, that they are thoroughly mixed during the deposition process or during post annealing, so that the film consist of a single homogeneous ternary (e.g. PbTiO₃), quaternary (e.g. Pb(Zr,Ti)O₃) or even more complicated solid compound.

Typically, the ALD reaction chamber is preheated to the deposition temperature to improve the throughput of the system. A substrate is loaded 202 in the reaction space of a single wafer reactor or several substrates are loaded in the reaction space of a batch reactor. The pressure of the reaction space is adjusted with a vacuum generator, e.g. a vacuum pump, and flowing inactive gas so that the substrate(s) are exposed to inactive gas flow 204.

Each pulsing cycle comprises four basic steps: precursor 1 pulse/purge/precursor 2 pulse/purge. In this example the first pulsing cycle is used for growing a lead oxide layer on the surface. Lead precursor vapor is pulsed to the reaction space 206. Pb precursor molecules chemisorb on heated surfaces of the reaction space including the substrate until available active surface sites have been consumed and the chemisorption process self-terminates. Residual Pb precursor molecules and gaseous by-products originating from the surface reactions are removed from the reaction space during the purge step 208. Then the substrate is exposed to oxygen precursor 210. Oxygen precursor molecules react with the chemisorbed Pb precursor molecules so that the ligands attached to lead are removed or burned away and oxygen forms a chemical bond with Pb on the surface. Residual oxygen precursor molecules and gaseous by-products, such as CO₂ and H2O, originating from the surface reactions are removed from the reaction space during the purge step 212. Typically, the surface reactions with the oxygen precursor leave hydroxyl (−OH) groups on the surface. These -OH groups serve as active sites for the chemisorption of the gas phase molecules of the subsequent metal precursor pulse. As a result, no more than a molecular layer of lead oxide is formed on the substrate surface in each pulsing cycle. The thickness increase of the thin film per pulsing cycle is typically much less than a molecular layer of PbO because of the bulky ligands attached to the chemisorbed Pb precursor molecule. Pulsing cycle counter is then checked 214 by the control program. If the predetermined thickness of the PbO sublayer, corresponding to specified number of pulsing cycles, is not yet reached, the first pulsing cycle is repeated 216 as many times as is needed. If the PbO sublayer is thick enough, the control program proceeds 218 to the second pulsing cycle.

In this example, the second pulsing cycle is used for adding a second metal, e.g. titanium (Ti), in the form of metal oxide, e.g. titanium dioxide (TiO₂), to the growing thin film, e.g. lead titanate (PbTiO₃). A second metal precursor is pulsed to the reaction space 220. The molecules of the second metal precursor chemisorb on the substrate surface until available active surface sites have been consumed and the chemisorption process self-terminates. Residual second metal precursor molecules and gaseous by-products originating from the surface reactions are removed from the reaction space during the purge step 222. Then, the substrate is exposed to oxygen precursor 224. Oxygen precursor molecules react with the chemisorbed second metal precursor molecules so that the ligands attached to the second metal are removed or burned away and oxygen forms a chemical bond with the second metal atoms on the surface. Residual oxygen precursor molecules and gaseous by-products, such as CO₂ and H₂O, originating from the surface reactions are removed from the reaction space during the purge step 226. As a result, no more than a molecular layer of second metal oxide is formed on the substrate surface. The thickness increase of the thin film per pulsing cycle is typically clearly less than a molecular layer of the second metal oxide because of the more or less bulky ligands attached to the chemisorbed second metal precursor molecule. Next, local pulsing cycle counter is checked 228 by the control program. If the predetermined thickness of the second metal oxide sublayer, corresponding to specified number of pulsing cycles, is not yet reached, the second pulsing cycle is repeated 230 as many times as is needed. If the second metal oxide sublayer is thick enough, the control program proceeds 232 to the global pulsing cycle counter 234 for checking whether or not the desired total thin film thickness has been reached. If the thin film is not thick enough, the first and the second pulsing cycles are repeated 236. If the film is thick enough, the process control exits 238 the global pulsing cycle loop and the handling of the substrate continues 240, e.g., with annealing, another thin film deposition process or patterning process steps.

The growth rate of lead oxide is usually smaller than the growth rate of the second metal oxide. Thus, the number of the repeated first pulsing cycles is typically larger than the number of the repeated second pulsing cycles. In case of stoichiometric PbTiO₃ deposition, the ratio of the first pulsing cycles (PbO growth) to the second pulsing cycles (TiO₂ growth) is preferably in the order of about 10:1 to about 30:1 depending on the deposition temperature and choice of precursors.

It is possible to reverse the order of metal oxides deposition. In that case the first pulsing cycle is used for depositing the second metal oxide (e.g. TiO₂) and the second pulsing cycle is used for depositing the lead oxide. Regarding stoichiometric PbTiO₃ deposition with reversed deposition order, the ratio of the first pulsing cycles (TiO₂ growth) to the second pulsing cycles (PbO growth) is now preferably in the order of about 1:10 to about 1:30, again depending on the deposition temperature and choice of precursors.

### CHEMICAL EXAMPLES

### EXAMPLE 2

### Materials And Methods

Film depositions were carried out in a commercial flow-type F-120 atomic layer deposition reactor (ASM Microchemistry Ltd.). The pressure was 2-3 mbar in the reactor during the studies on the thin film deposition at temperatures of 250 and 300° C. Tetraphenyllead (Ph₄Pb, Aldrich Chem. Co., 97%) and titanium isopropoxide (Ti(OⁱPr)₄, Aldrich Chem. Co., 97%) were used as metal precursors. The metal precursors were evaporated inside the reactor from open source boats kept at 165 and 40° C., respectively. The reactants were alternately introduced into the reactor by using nitrogen as carrier and purging gas. Nitrogen (>99.999%) was obtained from a nitrogen generator (Nitrox UHPN 3000-1). Ozone generated from oxygen (purity >99.999%) in an ozone generator (Fischer model 502) and water vaporized in a cylinder kept at 30° C. were used as oxygen sources for Ph₄Pb and Ti(OⁱPr)₄, respectively. The size of the Si(100) (Okmetic, Finland) substrates used was 5×10 cm².

At first, the deposition processes of binary oxides were studied in order to define the growth parameters for ternary oxide process. Uniform thin films were obtained when the reactant pulse durations used were 1.5 s and 0.6 s for Ph₄Pb and Ti(OⁱPr)₄, respectively. Pulse duration for O₃ was 2 s and for H₂O 1 s. Purging times were between 1-2 s, depending on the pulsing times of the previous precursor.

When depositing ternary PbTiO₃ thin films, the ratio of binary oxide layers was altered by changing the relative number of the Ph₄Pb/O₃ and Ti(OⁱPr)₄/H₂O pulses. The slash character denotes alternating sequential pulsing carried out according to the ALD method. The films were deposited by applying a plurality of lead oxide cycles followed by one titanium oxide cycle and then repeating that sequence. Typically, the number of lead oxide cycles was varied between 5 and 50. The total number of PbO/TiO₂ layers was varied in order to control the total film thickness.

Thicknesses of the deposited PbTiO₃ films were evaluated by Hitachi U-2000 spectrometer using the wavelength region 190-1100 nm. Pb and Ti contents were measured using Philips PW 1480 X-ray fluorescence spectrometer equipped with a Rh X-ray tube.

The amount of any impurities was measured by Time-of-Flight Elastic Recoil Detection Analysis (TOF-ERDA) from selected samples. TOF-ERDA measurements were carried out at the Accelerator Laboratory of the University of Helsinki.

The film crystallinity and preferred orientations were studied by X-ray diffraction (Philips MPD 1880) using Cu Ka radiation. Selected samples were annealed in an RTA oven (PEO 601, ATV Technologie GmbH, Germany) in N₂ or O₂ (>99-999%) atmosphere at 500-900° C. for 10 minutes at atmospheric pressure. The heating rate of 20° C./min and cooling rate of 25° C./min were used. Surface morphologies of selected samples were studied with an atomic force microscope (AFM) AutoProbe CP (Park Scientific Instruments/Veeco) operated in the intermittent-contact mode using Ultralevels™ (Veeco) silicon-cantilevers. Roughness was calculated as root-mean-square (rms) values.

Results

The growth rate of PbO thin films was found to be 0.13 Å/cycle at 250° C. and 0.10 Å/cycle at 300° C. when using 1-1.5 s pulsing times for Ph₄Pb. To obtain sufficient surface saturation, a pulse time of 1.5 s for Ph₄Pb was used when depositing PbTiO₃. Pulsing times were 2 s for ozone, 0.6-0.8 s for titanium isopropoxide and 1 s for water.

Because lead oxide had a lower growth rate than titanium dioxide, deposition of PbTiO₃ was started first with a variable number of lead oxide cycles (Ph₄Pb/O₃), followed by one cycle of titanium dioxide (Ti(OⁱPr)₄/H₂O). Under constant deposition temperature and pulsing ratio the film thickness of PbTiO₃ thin films was found to be linearly dependent on the number of depositing cycles.

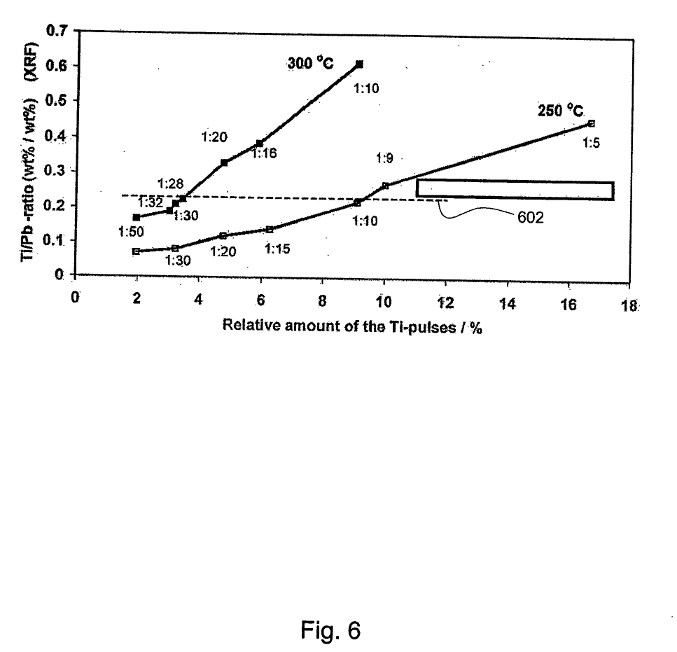

XRF measurements showed that the Ti/Pb atomic ratio in films was dependent on the relative amount of the titanium pulses as seen in FIG. 6. The XRF results were calibrated by plotting the XRF Ti/Pb-ratio against the Ti/Pb-ratio measured by RBS. Results were in good congruency with each other. Stoichiometric films were obtained at 250° C. with a Ti:Pb pulsing ratio of 1:10 and at 300° C. with a pulsing ratio of 1:28.

TOF-ERDA analyses performed showed that impurity levels were low and no other impurities than carbon and hydrogen were detected: carbon content was under 0.2 at-% and hydrogen content was 0.1-0.5 at-%.

### EXAMPLE 3

### Preparation of PbO₂ Films by Ph₄Pb/O₃ Process

Lead oxide thin films were grown by ALD using tetraphenyl lead Ph₄Pb as a lead precursor. The evaporation temperature was 165 to 170° C. The effect of the deposition temperature on the growth rate was studied over a temperature range of 185 to 400° C. for the Ph₄Pb/O₃ process. Pulsing times for Ph₄Pb were 1.0 to 3.0 s. The ozone pulse was varied in the range of 1.0 to 3.0 s and the nitrogen pulses between 1.0 and 2.5 s.

In case of Ph₄Pb, the growth rate decreased with increasing deposition temperatures. A constant growth rate of 0.13 Å/cycle was obtained at 200 to 250° C. The effect of the Ph₄Pb pulse times was examined at 250° C. and 300° C. The growth rate was almost independent of the pulse time at 300° C., and only a small increase in growth rate from 0.13 to 0.16 Å/cycle was observed at 250° C.

Films deposited by Ph₄Pb/O₃ process were polycrystalline, either orthorhombic (O) or tetragonal (T) lead dioxide (PbO₂). The most intense reflection was T(110) if depositions were carried out below 300° C. Above 300° C., orientation changed so that the most intense reflection was O(111).

According to TOF-ERDA, the lead-to-oxygen ratio was close to 0.7. Impurities levels were 0.5 at-% for carbon and less than 0.1 at-% for hydrogen at films deposited at 250° C.

Graphical Representations of the Results

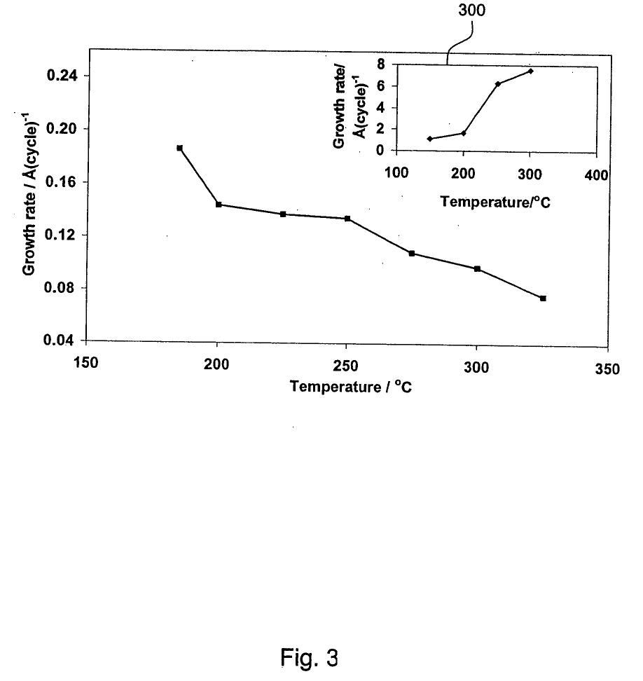

The attached drawings (FIGS. 3 to 7) depict graphically the results of ALD growth of lead oxide films:

FIG. 3 shows the growth rate of PbO₂ thin films as a function of the deposition temperature. Tetraphenyllead Ph₄Pb was used as the lead precursor and ozone O₃ was used as the oxygen precursor. The pulsing times for Ph₄Pb and O₃ were 1.0 s and 2.0 s, respectively. Constant growth rate of PbO₂ was obtained when the substrate temperature was in the range of 200-250° C. For a comparison, an insert 300 shows the growth rate of PbO₂ using Pb(thd)₂ and O₃ as precursors. The pulsing times for Pb(thd)₂ and O3 were 1.0 s and 1.5 s, respectively. The substrate temperature affected rather strongly the growth rate of PbO₂.

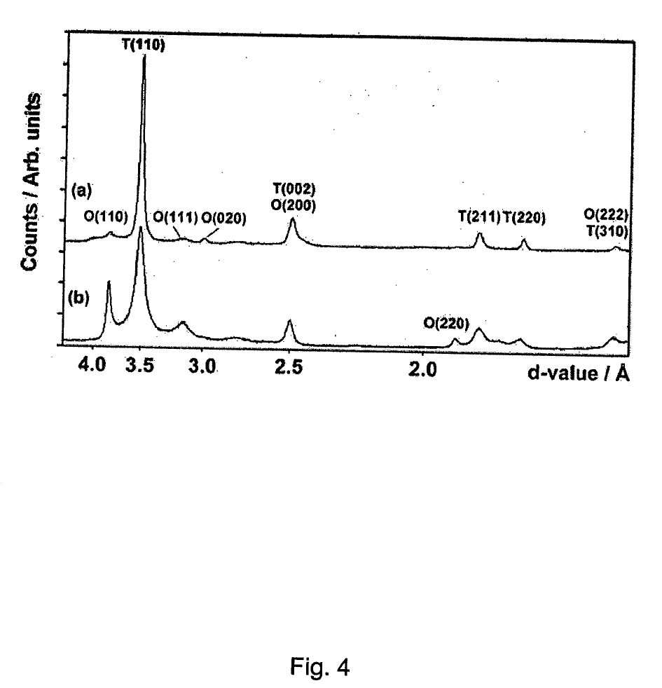

FIG. 4 shows XRD patterns of PbO₂ films deposited from Ph₄Pb at 250° C. (a) and from Pb(thd)₂ at 150° C. (b). The thickness for (a) was 70 nm and for (b) was 170 nm. Diffraction peeks were identified according to JCPDS cards 25-447 and 37-517.

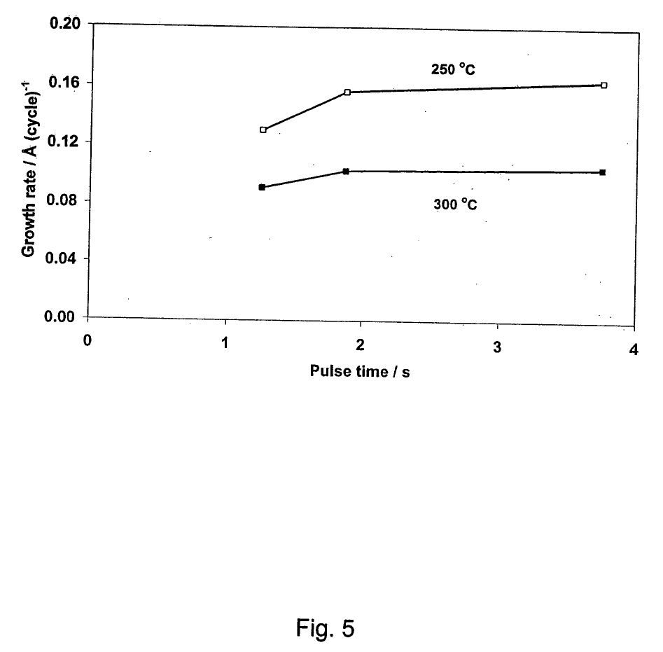

FIG. 5 shows the growth rate of lead oxide thin films deposited at 250° C. and 300° C. using Ph₄Pb as the Pb precursor with different Ph₄Pb vapour pulse lengths. Pulsing time for O₃ was 2.0 s and purging time 1.0-2.0 s depending on the precursor pulsing time.

FIG. 6 shows the ratio of titanium and lead content in Pb—Ti—O films deposited at 250° C. and 300° C. on Si(100) as a function of the precursor pulsing ratio. The film composition was measured by X-ray Fluorescence (XRF) and independently verified by Time-of-Flight Elastic Recoil Detection Analysis (TOF ERDA). Stoichiometric Pb—Ti oxide film is obtained when the Ti/Pb weight ratio is 0.23, shown with a horizontal dashed line 602.

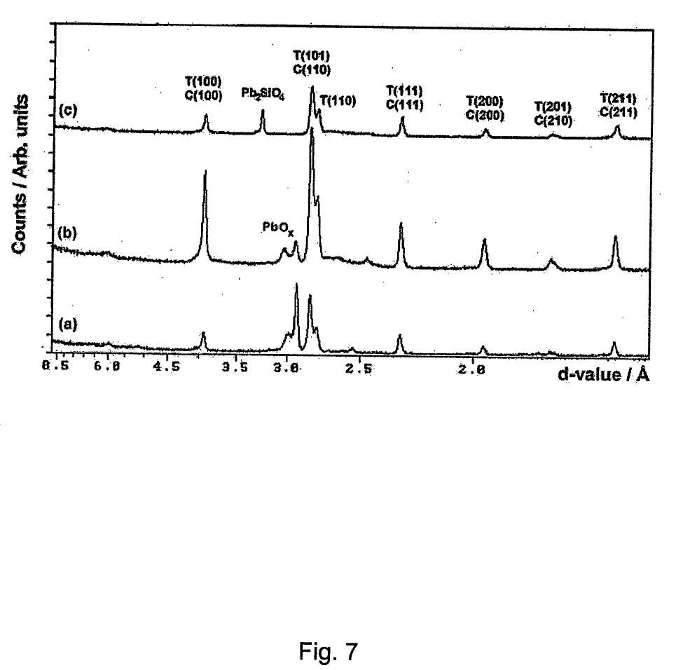

FIG. 7 shows X-ray Diffraction (XRD) patterns of PbTiO₃ films annealed at 800° C. (a), 900° C. (b), and 1000° C. (c) in nitrogen N₂ atmosphere for 10 min.

### COMPARATIVE EXAMPLE

### Preparation of PbO2 Films by a Pb(thd)2/O3 Process

For comparative purposes, lead oxide films were deposited at ALD conditions using as a precursor for lead an organometallic compound, in which the ligand is attached to the metal atom via oxygen-metal bonds.

The evaporation temperature for bis(2,2,6,6-tetramethyl-3,5-heptanedionato)lead Pb(thd)₂ was 110-115° C. The effect of the deposition temperature on the growth rate was studied over a temperature range of 150 to 300° C. Precursor pulsing and purging times were also studied in order to optimize the deposition process. Pulsing times studied for Pb(thd)₂ were 1.0-3.0 s. Ozone pulse was varied between 1.0 and 3.0 s and the purging nitrogen pulse was varied in the range of 1.0 to 2.5 s.

In the case of Pb(thd)₂ the growth rate increased with increasing deposition temperature. Also a clear thickness profile and dim and black film surface were observed at 250° C. and above. The growth rates for the Pb(thd)₂ process were 1.0 to 1.5 Å/cycle at temperatures below 200° C. and it increased up to 7.6 Å/cycle, when the deposition temperature reached 300° C.

Pulsing times for Pb(thd)₂ were examined at 150° C. At 1.0 s pulsing times, the films were smooth, and no differences were observed with longer pulsing times, indicating ALD type growth. The Pb(thd)₂ pulse was then kept constant at 1.0 s and the ozone pulse was fixed between 1.0 and 3.0 s.

The thin films deposited from Pb(thd)2 were all crystalline regardless of the deposition temperatures. Below 200° C. the films were polycrystalline with orthorhombic (O) and tetragonal (T) lead dioxide (PbO₂) phases. The most intense reflection at 150° C. was tetragonal (110), whereas at 200° C., the most intense reflection was orthorhombic (111).

According to TOF-ERDA, the lead-to-oxygen ratio was close to 0.7. The impurity levels were 1.1 at-% for carbon and 0.1 at-% for hydrogen for films deposited at 150° C.

While the invention has been described herein with reference to specific embodiments and features, one skilled in the art will recognize that various changes to the deposition conditions (e.g. substrate temperature and deposition pressure), precursor selections and thin film properties (e.g. composition, crystallinity and thickness) can be made without departing from the scope of the invention. Therefore, the scope of the invention should not be based upon the foregoing description. Rather, the scope of the invention should be determined based upon the claims recited herein, including the full scope of equivalents thereof.

What is claimed is:

1. A process for producing a lead oxide thin film by atomic layer deposition comprising using as a lead source material a metal-organic lead precursor having organic ligands bonded to a lead atom by carbon-lead bonds.

2. The process according to claim 1, wherein the lead source material is selected from the group consisting of tetraethyl lead and tetraphenyl lead.

3. The process according to claim 1, wherein the deposition temperature is about 150 to 400° C.

4. The process according to claim 1, wherein the metal-organic lead precursor comprises 2 or 4 alkyl ligands or ligands comprising aromatic groups.

5. The process according to claim 4, wherein the metal-organic lead precursor has the formula
L¹L²L³L⁴Pb
wherein each L¹, L², L³ and L⁴ is independently selected from the group consisting of:
linear or branched C₁-C₂₀ alkyl or alkenyl groups;
halogenated alkyl or alkenyl groups, wherein at least one hydrogen atom is replaced with fluorine, chlorine, bromine or iodine atom;
carbocyclic groups; and
heterocyclic groups.

6. The process according to claim 1, comprising alternately feeding into a reaction space vapor phase pulses of the metal-organic lead precursor and at least one oxygen source material.

7. The process according to claim 6, wherein the oxygen source material is selected from the group consisting of water, oxygen, hydrogen peroxide, aqueous solution of hydrogen peroxide, ozone, oxides of nitrogen, halide-oxygen compounds, peracids (—C(═O)— OOH), alcohols, alkoxides, oxygen-containing radicals and mixtures thereof.

8. The process according to claim 1, wherein the lead oxide thin film is a ternary oxide thin film.

9. The process according to claim 8, wherein the ternary oxide thin film comprises a second metal selected from the group consisting of bismuth, calcium, strontium, copper, titanium, tantalum, zirconium, hafnium, vanadium, niobium, chromium, tungsten, molybdenum, aluminum, rare earth metals and silicon.

10. The process according to claim 9, wherein the ternary oxide thin film comprises PbTiO₃.

11. The process according to claim 10, further comprising annealing the PbTiO₃ film at a temperature in excess of 500° C. in order to obtain a crystalline PbTiO₃ film.

12. The process according to claim 11, wherein the PbTiO₃ film is annealed at a temperature in excess of 800° C.

13. The process according to claim 11, wherein the PbTiO₃ film is annealed in an inert atmosphere or in the presence of oxygen.

14. The process according to claim 9, wherein the second metal is deposited from a second source material selected from the group consisting of halides and metal organic compounds.

15. The process according to claim 14, wherein the second source material is selected from the group consisting of alkoxy, alkylamino, cyclopentadienyl, dithiocarbamate and betadiketonate compounds.

16. The process according to claim 1, wherein the lead oxide thin film produced is a multicomponent oxide thin film.

17. The process according to claim 16, wherein the multicomponent oxide thin film comprises at least one further metal oxide selected from the group consisting of lanthanum oxide and zirconium oxide.

18. The process according to claim 17, wherein the multicomponent oxide thin film comprises Pb(Zr,Ti)O₃ or (Pb,La)(Zr,Ti)O₃.

19. The process according to claim 1, wherein the lead oxide thin film is an insulator layer in a memory structure.

20. A process for forming a lead containing multicomponent oxide thin film by atomic layer deposition on a substrate in a reaction space, comprising
alternately feeding into said reaction space vapor phase pulses of a first metal source material, a second metal source material, and at least one oxygen source material, wherein
said first metal source material is a metal-organic lead compound having optionally substituted alkyl or aryl ligands bonded by carbon-lead bonds to a lead atom, and
said second metal source material is a volatile compound of at least one transition metal or main group metal of groups 1, 2, 3, 4, 5, 6, 7, 8, 9, 10, 11, 12, 13, and/or 14 in the periodic table of elements.

21. The process according to claim 20, wherein a pulse of the first metal source material is followed by a pulse of the oxygen source material

22. The process according to claim 20, wherein the pulse of the oxygen source material is followed by a pulse of the second metal source material.

23. The process according to claim 20, wherein a pulse of the second metal source material is followed by a pulse of the oxygen source material.

24. The process according to claim 20, wherein the vapor phase pulses of the first metal source material, second metal source material and oxygen source material are provided in a plurality of deposition cycles, each cycle comprising, in order:
a pulse of the first metal source material;
a pulse of the oxygen source material;
a pulse of the second metal source material; and
a pulse of the oxygen source material.

25. The process according to claim 24, wherein in the plurality of deposition cycles the pulses of first metal source material and the pulses of second metal source material are provided at a ratio of about 50:1 to about 1:50.

26. The process according to claim 21, wherein said lead containing multicomponent oxide thin film is utilized in a semiconductor device.

27. A method of producing a lead oxide thin film in an integrated circuit by an atomic layer deposition (ALD) process in which each of a plurality of cycles comprises exposing an adsorbed metal-organic lead precursor on a substrate to an oxygen compound, the oxygen compound reacting with the adsorbed lead precursor in a self-limiting reaction to form no more than about one monolayer of lead oxide.

28. The method of claim 27, wherein the lead oxide thin film is a ternary oxide thin film.

29. The method of claim 27, wherein the lead oxide thin film is a multicomponent oxide thin film.
